(19) United States
(12) Patent Application Publication
(10) Pub. No.: US 2022/0085228 A1
(43) Pub. Date: Mar. 17, 2022

(54) Two-Dimensional Material Detector Based on Asymmetrically Integrated Optical Microstrip Antenna

(71) Applicant: Shanghai Institute of Technical Physics Chinese Academy of Sciences, Shanghai (CN)

(72) Inventors: Jing Zhou, Shanghai (CN); Shangkun Guo, Shanghai (CN); Yu Yu, Shanghai (CN); Zhaoyu Ji, Shanghai (CN); Xu Dai, Shanghai (CN); Jie Deng, Shanghai (CN); Xiaoshuang Chen, Shanghai (CN); Qingyuan Cai, Shanghai (CN); Zeshi Chu, Shanghai (CN); Fangzhe Li, Shanghai (CN); Mengke Lan, Shanghai (CN)

(73) Assignee: Shanghai Institute of Technical Physics Chinese Academy of Sciences, Shanghai (CN)

(21) Appl. No.: 17/447,731

(22) Filed: Sep. 15, 2021

(30) Foreign Application Priority Data
Sep. 15, 2020 (CN) 202010965512.7

(51) Int. Cl. H01L 31/101; H01Q 9/04; H01L 31/0232

(52) U.S. Cl. CPC H01L 31/1013; H01L 31/02327; H01Q 9/0407

(57) ABSTRACT

The present disclosure provides a two-dimensional material detector with an asymmetrically integrated optical microstrip antenna, structurally including a metal reflecting surface, a dielectric spacer layer, a two-dimensional active material layer, a top source electrode, and a drain electrode integrated with a metal strip array. Self-driven photoresponse of a metal/two-dimensional material/metal structure is induced by a Schottky junction formed due to contact between the two-dimensional material and the metal. The asymmetrically integrated optical microstrip antennas break the symmetry between the two contact/two-dimensional material junctions. Light absorption in the contact/two-dimensional material junction integrated with optical patch antennas is significantly enhanced by efficient light in-coupling and intensified light localization; meanwhile, the extended boundary of the contact/two-dimensional material junction enlarges the photocurrent collection area. The light absorption in the other contact/two-dimensional material junction is significantly inhibited by a metal bottom surface which is very close to the two-dimensional material.

### CROSS REFERENCE TO RELATED APPLICATION

This application claims priority to Chinese Patent Application No. 202010965512.7, filed Sep. 15, 2020, which is herein incorporated by reference in its entirety.

### TECHNICAL FIELD

The present disclosure relates to a two-dimensional material detector with asymmetrically integrated optical microstrip antennas, and in particular, to a two-dimensional material detector with asymmetrically integrated optical microstrip antennas allowing for self-driven photoresponse enhancement, and a design method thereof.

### BACKGROUND ART

At present, photodetectors have been widely used in optical fiber communication, optical imaging, remote sensing, and biomedical analysis systems and have become an essential part in daily life. Unfortunately, photodetectors must meet certain requirements to be specifically used in related industries and researches. Due to different working waveband needs, it must be careful to select the energy band gap of a semiconductor material for manufacturing a photodetector to match a corresponding working wavelength. In the past ten years, emerging two-dimensional layered materials promoted the research on novel photodetectors. Different two-dimensional materials typically possess different band gaps and thus cover almost all wavelengths of interest that cannot be covered by existing traditional bulk semiconductor materials. Two-dimensional materials can be electrostatically controlled in a prominent manner due to their ultra-small thicknesses. When most of the intrinsic carriers are depleted by a local gate voltage, the dark current can be significantly suppressed. In addition, two-dimensional materials can be integrated with most substrates and other two-dimensional materials without consideration of strict lattice matching, which is a big advantage over traditional materials. Moreover, two-dimensional materials have a promising application prospect in photodetection because their manufacturing processes are compatible with current semiconductor technologies.

It is impractical to provide a power supply for each piece of equipment in many applications such as outdoor environmental monitoring and wearable medical monitoring based on wireless sensor networks. In these fields, self-driven or ultralow-power photodetectors are more suitable for practical application. To achieve self-driven photodetectors, various device structures are proposed, among which the most studied device is a p-n junction-based photovoltaic device because it can generate a self-driven photocurrent through the photovoltaic effect in a zero-bias state. Since so far there is no generally reliable doping method for two-dimensional materials. Two-dimensional heterojunctions or split-gate structures are adopted to form p-n junctions of two-dimensional materials. The problem of the former is that a two-dimensional heterojunction may be greatly affected by the different band structures of the heterogeneous materials and especially affected by the interface. Thus, it is difficult to effectively control the transport property of carriers. The problem of the latter is that the split-gate structure is complex to fabricate, leading to a low yield and a high cost. The contact between a metal and a two-dimensional material can result in a Schottky-like junction and then electrons and holes can be separated to produce a self-driven photoresponse. Since a common metal/two-dimensional material/metal device structure has symmetrical metal/two-dimensional material junctions, the self-driven photoresponses produced at two contacts are canceled out, and there is no net photoresponse under floodlighting. Self-driven net photoresponse under floodlighting can be obtained by introducing dissimilar metal electrodes to obtain different Schottky barrier heights. However, dissimilar metal structures require additional fabrication processes such as overlay, deposition, and stripping. These processes are complicated and prone to cause pollution and damage to two-dimensional materials, finally resulting in a decreased yield of devices. Therefore, it is of great significance to develop a simple and reliable two-dimensional material based photodetector with self-driven photoresponse. Asymmetrically integrated nanophotonic structures can break the symmetry of metal/two-dimensional material junctions at two contacts, which provides a new idea for researchers. In another aspect, ultrathin two-dimensional materials may have low light absorptivity, so that light is mostly reflected or transmitted without being absorbed. Accordingly, the asymmetrically integrated micro-nano optical structure is required to enhance light absorption of the two-dimensional material while breaking the symmetry. To sum up, an asymmetrically integrated optical microstrip antenna is a highly promising candidate. The optical microstrip antenna may be fused with one electrode so that light absorption in this contact/two-dimensional material junction is significantly enhanced by efficient coupling to a local light field; and also by the extended boundary of the contact/two-dimensional material junction. Moreover, in the junction region at the other contact, light absorption may be significantly inhibited by a metal bottom surface, which is very close to the two-dimensional material. These two effects lead to a tremendous difference in photoresponse at the two contacts of the metal//two-dimensional/metal device. As a result, a two-dimensional material based optical detection device with significant self-driven photoresponse can be created.

### SUMMARY

An objective of the present disclosure is to provide a two-dimensional material detector with an asymmetrically integrated optical microstrip antenna array that allows for self-driven photoresponse enhancement, and a design method thereof. The problems of zero net self-driven photoresponse by a classical metal/graphene/metal photodetector and low light absorptivity of graphene are solved.

FIG. 1 shows a structure of a graphene detector with an asymmetrically integrated optical microstrip antenna array that allows for enhancement of self-driven photoresponse according to the present disclosure. The detector structurally includes a metal reflecting surface 1, a dielectric spacer layer 2, a two-dimensional active material layer 3, a source electrode 4, and a drain electrode 5 integrated with a metal strip array, as shown in the figure. The metal reflecting surface 1, the dielectric spacer layer 2, and a metal strip are combined to form an optical microstrip antenna.

The metal reflecting surface 1 may be a complete metal reflecting layer with a thickness h₁ no less than twice the skin depth of the electromagnetic waves in the metal. The metal reflecting surface 1 may be made of a metal with high electrical conductivity. The metal material can be but not limited to gold, silver, aluminum, and their alloys.

The dielectric spacer layer 2 may be a dielectric layer that is transparent to the working waveband and has a thickness h₂. The material may be but not limited to specifically aluminum sesquioxide, silicon dioxide, magnesium fluoride, zinc sulfide, and hafnium oxide. The optical thickness should be smaller than one-quarter of the wavelength.

The two-dimensional active material 3 may be a material with a thickness of an atomic scale.

The source electrode 4 and the drain electrode 5 integrated with a metal strip array may be formed by a layer of a high electrical conductivity metal with a thickness h₃. The thickness h₃ may be not less than twice the skin depth of electromagnetic waves in the metal. The structure may be determined by a strip array period P, a strip line width W, a strip length L₁, and a channel length L₂, where L₁ is equal to L₂/2. P ranges from one-quarter to one-half of an optical wavelength, and W ranges from one-third to one-half of P.

In this device, the optical microstrip antenna is integrated with graphene, and the light field of a subwavelength local photon mode is enhanced by a plasmonic cavity resonance. Then, the light absorption and the photoresponse of graphene are enhanced. When light is incident on the graphene detector integrated with the optical microstrip antenna, a plasmonic waveguide mode is formed in the dielectric layer between the top and bottom metals. This mode propagates horizontally and gets reflected at the cavity boundaries defined by the top metal. When an optical wavelength and a length of the resonant cavity meet the condition of constructive interference, Fabry-Perot-like cavity resonance occurs. The impedance matching of the optical microstrip antenna is tuned by adjusting parameters such as the period of the metal strip array and the thickness of the dielectric layer to push the system to a critical coupling state, so that incident electromagnetic waves are efficiently converted into a local light field under each metal strip. As a result, the light-graphene interaction is enhanced, and thereby the absorptance and the photoresponse of graphene are improved. The optical microstrip antenna may be fused with an electrode at one end, and then light absorption in the contact junction region at this electrode is significantly enhanced by efficient light in-coupling and localization. Meanwhile, the boundary of the contact-graphene junction is extended and thus the receiving efficiency of photoelectric current is improved. Moreover, in the contact-graphene junction at the other electrode, light absorption may be significantly inhibited by a metal bottom surface that is very close to the two-dimensional material. As a result, there is a tremendous difference between the photoresponses at the two contact/two-dimensional material junctions. As a result, a two-dimensional material based photodetector with significant self-driven photoresponse is created.

The present disclosure has the following advantages:

1. In this structure, the metal strip array is used as an extension of the drain electrode. Due to the efficient coupling of the optical microstrip antenna and the local light field, the light absorption is greatly enhanced in the contact/graphene junction area. In addition, the photocurrent collection efficiency is enhanced due to the extended boundary of the contact junction. Since the graphene at the source electrode is very close to the bottom flat metal surface, the light field is suppressed, and then the light absorption and photoresponse are weakened. In the end, the photoresponse at the contact with the metal strip array is more than one hundred times larger than that at the other one. As a result, the metal/graphene/metal photodetector has net self-driven photoresponse under floodlighting.

2. The graphene detector integrated with the optical microstrip antenna can have a responsivity more than one order of magnitude higher than that of a traditional graphene detector integrated with a light-coupling metal grating.

3. The optical structure of the detector and the active material are integrated on the substrate, which can be achieved easily due to high process compatibility. The fabrication process is simple. The dark current of the device is inhibited while the self-driven mode is in operation.

### BRIEF DESCRIPTION OF THE DRAWINGS

FIG. 1 is a schematic diagram of a graphene photodetector asymmetrically integrated with an optical microstrip antenna.

FIG. 2 is a photovoltage waveform diagram obtained by irradiating a laser spot at two positions (marked in FIG. 1).

FIG. 3 is a schematic diagram of a graphene photodetector asymmetrically integrated with an optical microstrip antenna under floodlighting.

FIG. 4 is a diagram showing the responsivity spectra of two devices under floodlighting.

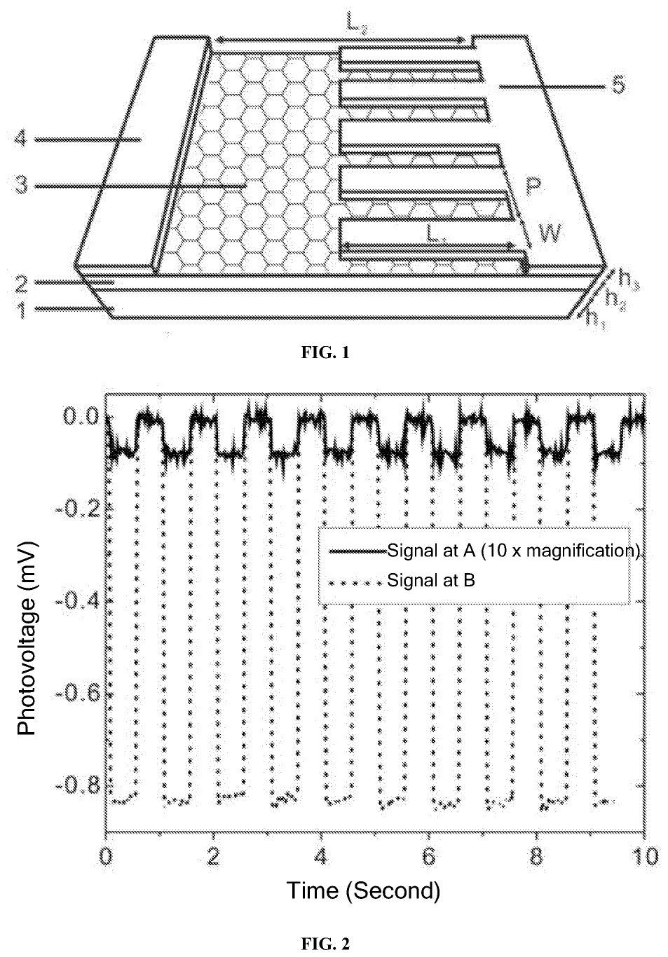

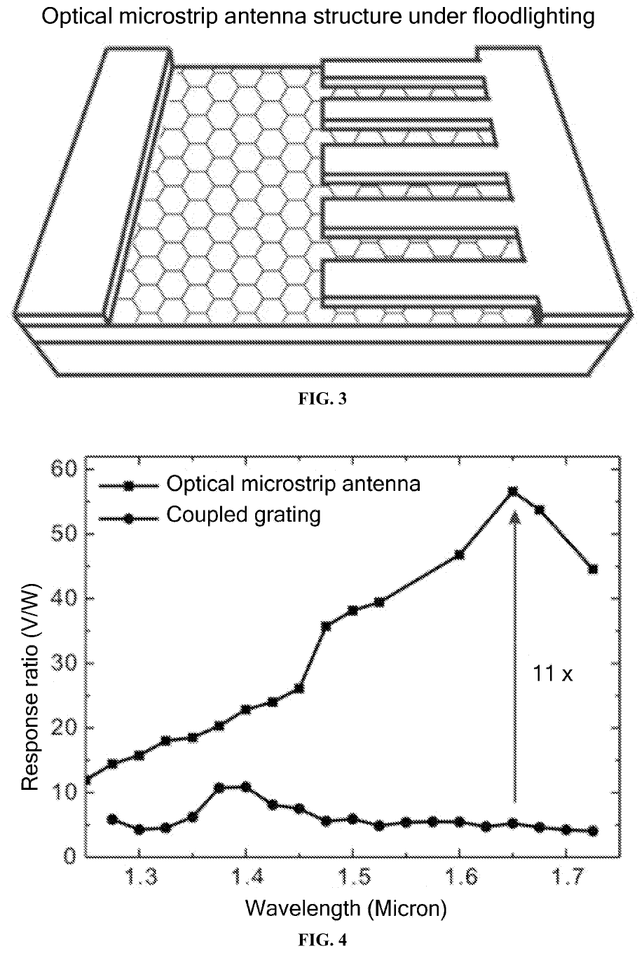

### DETAILED DESCRIPTION OF THE EMBODIMENTS

According to the present disclosure, the fabrication of the two-dimensional material detector with asymmetrically integrated optical microstrip antennas for self-driven photoresponse enhancement is compatible with a traditional semiconductor process. For ease of description, a specific embodiment of the present disclosure will be described below by taking a graphene detector with asymmetrically integrated optical microstrip antennas working at 1.55 μm as an example:

1. A silicon wafer substrate is first ultrasonically cleaned with acetone, and the surface of the silicon wafer is rinsed with isopropanol to remove excess acetone. The silicon wafer is then rinsed with deionized water and dried to ensure that the surface of the silicon wafer substrate is clean and pollution-free.

2. A metal layer of Cr (20 nm)/Au (90 nm) is deposited on the clean silicon wafer substrate as a bottom metal reflecting layer.

3. A dielectric spacer layer (2) that is transparent to a working waveband is deposited by using plasma-enhanced atomic layer deposition (PEALD) on the bottom metal reflecting layer. The thickness of layer (2) is specifically designed according to the requirement of the optical microstrip antenna.

4. A single layer of graphene grown by copper-based chemical vapor deposition (CVD) was transferred to the surface of the dielectric spacer layer (2) by using wet transfer techniques.

5. Patterns are defined by electron beam lithography. An electron beam photoresist is used as a mask to protect the underlying graphene, and oxygen plasma is used to etch the graphene that is not protected by the photoresist. Thus, the graphene patterning is achieved.

6. Metal contacts and photonic structures are created by electron beam lithography, metal deposition, and lift-off processing. With a photoresist as a mask, Cr (5 nm) and Au (45 nm) are deposited in sequence by electron beam evaporation. Finally, the source and drain electrodes and a metal strip array are obtained by the lift-off process.

### EXAMPLE

The graphene detector with asymmetrically integrated optical microstrip antennas in this example works at a wavelength of 1.65 μm. An optimized periodic unit was designed with the following structural dimensions: P=590 nm, W=283 nm, L₁=5 μm, L₂=10 μm, h₁=110 nm, h₂=30 nm, and h₃=45 nm. The metal reflecting layer (1) was formed by Cr (20 nm)/Au (90 nm). The dielectric spacer layer (2) was an aluminum sesquioxide dielectric layer that was transparent to the working waveband. The thickness of layer (2) is specifically designed according to the requirement of the optical microstrip antenna. The two-dimensional active material (3) was a single layer of graphene grown by copper-based CVD and transferred by a wet chemistry method. The source electrode (4) and the drain electrode (5) integrated with the metal strip array were made of Cr (5 nm)/Au (45 nm). As a reference control, a common graphene device was asymmetrically integrated with a light-coupling grating with the same structural dimensions of the top metal strip array in the graphene detector with asymmetrically integrated optical microstrip antennas. The substrate of the control device was 500 μm thick silicon and the intermediate dielectric spacer layer was 300 nm silicon dioxide.

1. A two-dimensional material detector with an asymmetrically integrated optical microstrip antenna array, structurally comprising from bottom to top:
a metal reflecting surface, a dielectric spacer layer, a two-dimensional active material layer, a source electrode, and a drain electrode integrated with a metal strip array, wherein the drain electrode integrated with a metal strip array, the dielectric spacer layer and the metal reflecting surface are combined to form an optical microstrip antenna;
wherein the metal reflecting surface is a metal reflecting layer with a thickness no less than twice a skin depth of electromagnetic waves in the metal; wherein the metal reflecting surface also works as a gate to electrostatically control the two-dimensional material and is made of a metal with high electrical conductivity;
wherein the dielectric spacer layer is a layer of a dielectric transparent to a working waveband, and an optical thickness is smaller than one-quarter of the wavelength;
wherein the two-dimensional active material is a material with an atomic thickness;
wherein the source electrode and the drain electrode integrated with a metal strip array are formed by a layer of a high electrical conductivity metal with a thickness no less than twice a skin depth of the electromagnetic waves in the metal, with a structure being determined by a strip array period, a strip line width a strip length and a channel length, wherein the strip length is half of the channel length; and wherein the strip array period ranges from one quarter to one half of an optical wavelength, and the strip line width ranges from one third to one half of the strip array period.
